(19) United States
(12) Patent Application Publication
(10) Pub. No.: US 2001/0014530 A1
(43) Pub. Date: Aug. 16, 2001

(54) METHOD FOR MANUFACTURING A SEMICONDUCTOR DEVICE

(76) Inventor: NAOKI KOIDO, YOKOHAMA-SHI (JP)

Correspondence Address: FOLEY & LARDNER, SUITE 500, 3000 K STREET NW, WASHINGTON, DC, 200075109

(21) Appl. No.: 09/060,075

(22) Filed: Apr. 15, 1998

(30) Foreign Application Priority Data
Apr. 15, 1997 (JP) 9-097235

(51) Int. Cl. H01L 21/4763

(52) U.S. Cl. 438/639

(57) ABSTRACT

In a semiconductor device having a contact structure, a semiconductor element is formed on the surface of a semiconductor substrate and an inter-level insulating film is formed on the entire surface. Then, an insulating film having a high etching selective ratio with respect to the inter-level insulating film is formed on the inter-level insulating film. After this, the thus formed insulating film is etched back and left behind only on the side wall of a stepped portion caused in the inter-level insulating film which defines a contact hole forming area. Then, a contact hole having an upper end portion formed in a forward tapered form is formed in the inter-level insulating film by use of a SAC technique using an insulating film left on the side wall of the stepped portion as the etching stopper. Since the contact hole having an upper end portion formed in a tapered form is formed, the margin for the short circuit between the side wall portion of the contact hole and the semiconductor element can be sufficiently large while the area of the bottom portion of the contact hole can be kept large, and thus the reliability of the semiconductor device can be enhanced.

### BACKGROUND OF THE INVENTION

This invention relates to a semiconductor device and a method for manufacturing the same, and more particularly to a contact portion having contact holes each having an upper end portion formed in a forward tapered form and a method for forming the same.

Recently, the contact size becomes smaller as a semiconductor device is miniaturized. In order to attain a good contact characteristic by connecting an interconnection layer via a contact hole with high aspect ratio, a technology for filling a conductive material into the contact hole in a good condition is required. As the technology, for example, the blanket method and refractory metal reflow method are known. When using the above methods, it is effective to form the side wall of the contact hole in a tapered form. The reason is that the conductive material is filled into the contact hole in the good condition so as to form a plug in a desired form or form a barrier metal layer which is an underlying layer of the plug in the good condition.

A conventional method for forming a contact hole containing the step of forming the side wall in a forward tapered form is explained by taking an EPROM as an example.

First, as shown in FIG. 12, material layers for first gate oxide films 2, floating gates 3, second gate oxide films 4 and control gates 5 are sequentially formed on the surface of a semiconductor substrate 1 by the known manufacturing method and the material layers are patterned to form laminated gate structures 6. Then, impurities are ion-implanted into the surface area of the semiconductor substrate 1 so as to form source/drain regions 20. After this, a material layer for a inter-level insulating film 7 which is formed of SiO₂ or SiO₂ containing impurity such as PSG or BPSG is formed on the surface of the semiconductor substrate 1 and the laminated gate structure 6 by the atmospheric pressure chemical vapor deposition method (which is hereinafter referred to as the CVD method) and the material layer is subjected to the reflow process in the heat treatment to form the inter-level insulating film 7.

Next, as shown in FIG. 13, a contact hole 9 is formed by etching a contact hole forming portion of the inter-level insulating film 7 with a photoresist 8 used as a mask. At this time, by using the reactive ion etching method (which is hereinafter referred to as the RIE) in which conditions of, for example, gas, temperature and pressure are optimized, the side wall portion of the contact hole 9 is formed with a forward tapered form.

After this, an EPROM shown in FIG. 14 is formed by removing the photoresist 8.

By the above manufacturing process, the contact hole 9 with the side wall portion formed in the forward tapered form can be formed.

However, with the conventional manufacturing method for the semiconductor device, if the side wall portion of the small contact hole 9 is formed in the forward tapered form, the area of the bottom portion of the contact hole 9 becomes small, thereby causing a problem that the reliability of the contact will be lowered and the contact resistance is increased. On the other hand, if the bottom portion of the contact hole is made sufficiently large, a larger area is required in the upper end portion of the contact hole, thereby causing a problem that the density of elements is lowered and the margin for the short circuit between the laminated gate structure 6 and the contact hole 9 cannot be made sufficiently large.

As a method for realizing the laminated gate structure 6 and the contact hole 9 with the minimum margin, a self-alignment contact (SAC) technique for forming contacts between interconnection layers in a self-alignment manner is known. FIG. 15 is a cross sectional view showing a contact hole forming portion formed by use of the above SAC technique and a neighboring portion thereof. With the SAC technique, after a laminated gate structure 6 whose upper surface is covered with, for example, a silicon nitride (which is hereinafter referred to as SiN) film having a high etching selective ratio with respect to an inter-level insulating film is formed on a semiconductor substrate 1, an insulating film such as an SiN film is formed on the entire surface of the semiconductor substrate 1 and then the insulating film is etched back to leave an insulating film 10a on at least the side wall portion of the laminated gate structure 6. Then, an inter-level insulating film 7 is formed on the entire surface of the semiconductor substrate with the above structure and contact holes 9 are formed in the inter-level insulating film 7. At this time, by using the insulating film 10 on the upper surface of the laminated gate structure 6 and the insulating film 10a on the side wall portion as stoppers of the etching, the contact holes 9 can be formed in the self-alignment manner.

However, since, in the SAC technique, the insulating film 10a such as an SiN film which has large stress on the gate oxide film is formed on the side wall portion of the laminated gate structure 6, the first and second gate oxide films 2 and 4 are deteriorated and the hot carrier resistance of the memory cell transistor is lowered. Further, in the EPROM, application of ultraviolet rays is normally performed in the erasing operation, and in a nonvolatile semiconductor memory device such as an EEPROM for effecting the electrically erasing operation, ultraviolet rays may be used for erasing and initialization of memory cell transistors at the time of test of the product before shipment or at the time of development of products. However, if the memory cell transistor is covered with a film such as an SiN film which is difficult to pass ultraviolet rays therethrough, the erasing operation cannot be performed or it takes a long time to effect the erasing operation.

As described above, in the conventional semiconductor device having contact holes formed in the forward tapered form, the reliability of the contact is lowered and the contact resistance is increased with the miniaturization of the contact hole, and if an attempt is made to solve the above problem, the integration density of the elements is lowered and the margin for the short circuit of the conductive layer cannot be made sufficiently large. Further, if the manufacturing method for the conventional semiconductor device using the SAC technique is used for a semiconductor element having a gate oxide film, the gate oxide film is deteriorated so that the hot carrier resistance will be lowered. Further, if the semiconductor element is a nonvolatile memory cell transistor, ultraviolet rays will not easily pass therethrough and it takes a long time to perform the erasing operation or initialization by application of ultraviolet rays.

### BRIEF SUMMARY OF THE INVENTION

This invention has been made in view of the above fact and an object of this invention is to provide a semiconductor device having a contact structure whose reliability can be enhanced by attaining a sufficiently large margin for the short circuit between the side wall portion of the contact hole and the semiconductor element while keeping the area of a bottom portion of the contact hole sufficiently large and a method for manufacturing the same.

Further, another object of this invention is to provide a semiconductor device capable of preventing degradation of the hot carrier resistance due to deterioration of the gate oxide film and a method for manufacturing the same.

Further, still another object of this invention is to provide a semiconductor device capable of reducing time required for effecting the erasing operation and initialization by applying ultraviolet rays to nonvolatile memory cell transistors and a method for manufacturing the same.

A semiconductor device of this invention comprises a semiconductor substrate; a semiconductor element formed on a surface of the semiconductor substrate; an inter-level insulating film formed above the surface of the semiconductor substrate to cover the semiconductor element; a contact hole formed in the inter-level insulating film and having at least an upper end portion formed in a forward tapered form; an insulating film formed on the upper end portion of the contact hole; and a conductive filling material layer filled in the contact hole. Thus, since the upper end portion of the contact hole is formed in the forward tapered form, the margin for the short circuit between the side wall portion of the contact hole and the semiconductor element can be made large while the area of the bottom portion of the contact hole is kept large and thus the reliability thereof can be enhanced. Further, when this invention is applied to a semiconductor element having a gate oxide film, deterioration of the gate oxide film can be prevented since the inter-level insulating film is formed between the insulating film giving large stress on the gate oxide film and the semiconductor element, and thus the hot carrier resistance will not be lowered. Further, if the semiconductor element is a nonvolatile memory cell transistor, the insulating film which is difficult to pass ultraviolet rays therethrough is formed only on the upper end portion of the contact hole, and therefore, time required for the erasing operation or initialization by application of ultraviolet rays can be reduced.

The above semiconductor device has a feature that an impurity diffusion layer formed in a surface area of the semiconductor substrate in a bottom portion of the contact hole may be additionally provided. Thus, if the impurity diffusion layer is provided in the semiconductor substrate in the bottom portion of the contact hole, the contact resistance can be reduced and the punch-through in the junction can be prevented.

Further, the above semiconductor device has a feature that an interconnection layer formed on the inter-level insulating film and the filling material layers and electrically connected to the semiconductor element via the filling material layer may be additionally provided. Thus, if the interconnection layer is formed on the inter-level insulating film and the filling material layer, the interconnection layer can be formed on the flat area, and therefore, defective interconnection due to breakage of the interconnection layer at the stepped portion can be suppressed.

Further, the above semiconductor device has a feature that a barrier metal layer formed between the filling material layer and a surface area of the semiconductor substrate in a bottom portion of the contact hole may be additionally provided. If the barrier metal layer is thus additionally provided, the reliability of the contact hole can be further enhanced.

The above semiconductor device has a feature that the semiconductor element may be a nonvolatile memory cell transistor. If the nonvolatile memory cell transistor is formed as the semiconductor element, time required for the erasing operation or initialization at the time of application of ultraviolet rays can be reduced since the insulating film which is difficult to pass ultraviolet rays therethrough covers only the upper end portion of the contact hole.

In the above semiconductor device, the insulating film formed on the upper end portion of the contact hole may be formed of a material having a high etching selective ratio with respect to a material of the inter-level insulating film. If a material having a high etching selective ratio with respect to the material of the inter-level insulating film is used as the material of the insulating film formed on the upper end portion of the contact hole, the contact hole can be formed in the inter-level insulating film by use of the SAC technique using as the etching stopper the insulating film formed on the upper end portion of the contact hole.

In the above semiconductor device, the insulating film formed on the upper end portion of the contact hole may be formed of an etching stopper material with regard to a material of the inter-level insulating film. If an etching stopper material with regard to the material of the inter-level insulating film is used as the material of the insulating film formed on the upper end portion of the contact hole, the contact hole can be formed in the inter-level insulating film by use of the SAC technique using as the etching stopper the insulating film formed on the upper end portion of the contact hole.

In the above semiconductor device, the inter-level insulating film may include silicon oxide and the insulating film formed on the upper end portion of the contact hole may include a silicon nitride film. Thus, a material containing silicon oxide can be used as a material of the inter-level insulating film and a silicon nitride film can be used as the insulating film formed on the upper end portion of the contact hole.

Further, a method for manufacturing the semiconductor device comprises the steps of forming a semiconductor element on a surface of a semiconductor substrate; forming an inter-level insulating film above the surface of the semiconductor substrate to cover the semiconductor element; forming an insulating film having a high etching selective ratio with respect to the inter-level insulating film on the inter-level insulating film; etching back the insulating film to leave a portion of the insulating film on a side wall of a stepped portion of a contact hole forming area on the inter-level insulating film; and etching the inter-level insulating film by use of the insulating film left on the side wall of the stepped portion on the inter-level insulating film as an etching stopper to form a contact hole having an upper end portion formed in a forward tapered form in the inter-level insulating film. Since the contact hole having the upper end portion thereof formed in the forward tapered form is thus formed on the inter-level insulating film as the etching stopper, by using the portion of the insulating film left on the side wall of the stepped portion, a sufficiently large margin for the short circuit between the side wall portion of the contact hole and the semiconductor element can be attained while the area of the bottom portion of the contact hole is kept sufficiently large and thus the reliability of the semiconductor device can be enhanced. Further, if the above method is applied to a manufacturing method for a semiconductor device including a semiconductor element having a gate oxide film, deterioration of the oxide film can be prevented even when the contact hole is formed by use of the SAC technique since the inter-level insulating film is formed between the insulating film having large stress on the gate oxide film and the semiconductor element, and thus, the hot carrier resistance will not be lowered. Further, if the semiconductor element is a nonvolatile memory cell transistor, time required for the erasing operation or initialization by application of ultraviolet rays can be reduced since the insulating film which is difficult to pass ultraviolet rays therethrough is formed only on the upper end portion of the contact hole.

The above manufacturing method has a feature that a step of ion-implanting impurity into a surface area of the semiconductor substrate in a bottom portion of the contact hole may be additionally provided. If an impurity diffusion layer is thus formed by ion-implanting impurity into the surface area of the semiconductor substrate in the bottom portion of the contact hole, the contact resistance can be reduced and the punch-through in the junction can be prevented.

The above manufacturing method has a feature that a step of filling a conductive filling material layer by filling a conductive filling material into the contact hole may be additionally provided. When the filling material layer is filled into the contact hole, the filling process can be easily effected since the upper end portion of the contact hole is formed in the forward tapered form.

The above manufacturing method has a feature that a step of forming an interconnection layer on the inter-level insulating film and the filling material layer may be additionally provided. If the interconnection layer is formed after the filling material layer is filled into the contact hole, the interconnection layer can be formed on a flat area and defective interconnection due to breakage of the interconnection layer at the stepped portion can be suppressed.

The above manufacturing method has a feature that the interconnection layer may be formed by depositing a metal on the inter-level insulating film and the filling material layer.

The above manufacturing method has a feature that a step of forming a barrier metal layer in the contact hole may be additionally provided. If the barrier metal layer is thus formed, the reliability of the contact can be further enhanced.

The above manufacturing method has a feature that the inter-level insulating film may be formed by using atmospheric pressure CVD method.

The above manufacturing method has a feature that the insulating film having the high etching selective ratio may be formed by using low pressure CVD method.

The above manufacturing method has a feature that the conductive filling material may be formed by using low pressure CVD method and isotropic etching method.

The above manufacturing method has a feature that the step of forming the semiconductor element may include a step of forming a first gate insulating film on the semiconductor substrate, a step of forming a floating gate on the first gate insulating film, a step of forming a second gate insulating film on the floating gate, a step of forming a control gate on the second gate insulting film, and a step of forming source and drain regions in the semiconductor substrate. Thus, if the above semiconductor method is applied to a manufacturing process for a nonvolatile memory cell transistor, the gate insulating films will not be deteriorated if the contact hole is formed by use of the SAC technique since the inter-level insulating film is formed between the insulating film which has large stress on the gate insulating films and the semiconductor element, and thus, the hot carrier resistance will not be lowered. Further, time required for the erasing operation or initialization by application of ultraviolet rays since the insulating film which is difficult to pass ultraviolet rays therethrough covers only the upper end portion of the contact hole.

The above manufacturing method has a feature that the inter-level insulating film may include a silicon oxide film formed by the CVD method and the insulating film having the high etching selective ratio includes a silicon nitride film formed by the CVD method. If a material containing the silicon oxide film formed by the CVD method is used as the inter-level insulating the CVD method is used as the inter-level insulating film and the silicon nitride film formed by the CVD method is used as the insulating film having the high etching selective ratio, the semiconductor device can be easily formed by use of the normal semiconductor device manufacturing method.

The above manufacturing method has a feature that a step of subjecting the inter-level insulating film to a reflow process before forming the insulating film having the high etching selective ratio may be additionally provided. If the step of subjecting the inter-level insulating film to the reflow process is provided, the degree of flatness of the inter-level insulating film is enhanced so as to suppress the insulating film having the high etching selective ratio from being left behind on unwanted portions.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinbefore.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a plan pattern view showing a NAND type EEPROM according to an embodiment of the present invention;

FIG. 2 is a cross sectional view showing the NAND type EEPROM of the embodiment of the present invention, taken along the II-II line of FIG. 1;

FIG. 3 is a cross sectional view showing a device structure in one manufacturing step, particularly, a contact hole and a neighboring structure thereof by taking the NAND type EEPROM of FIGS. 1 and 2 as an example, for explaining a semiconductor device and a method for manufacturing the same according to this invention;

FIG. 4 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 5 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 6 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 7 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 8 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 9 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 10 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 11 is a cross sectional view showing a device structure in one manufacturing step, particularly, a contact hole and a neighboring structure thereof by taking the NAND type EEPROM of FIGS. 1 and 2 as an example, for explaining the semiconductor device and the method for manufacturing the same according to this invention;

FIG. 12 is a cross sectional view showing a device structure in one manufacturing step, particularly, a contact hole and a neighboring structure thereof by taking an EPROM as an example, for explaining a method for manufacturing a conventional semiconductor device including contact holes whose side wall is forwardly tapered;

FIG. 13 is a cross sectional view showing a device structure in one manufacturing step, particularly, a contact hole and a neighboring structure thereof by taking an EPROM as an example, for explaining the method for manufacturing the conventional semiconductor device including contact holes whose side wall is forwardly tapered;

FIG. 14 is a cross sectional view showing a device structure in one manufacturing step, particularly, a contact hole and a neighboring structure thereof by taking an EPROM as an example, for explaining the method for manufacturing the conventional semiconductor device including contact holes whose side wall is forwardly tapered; and

FIG. 15 is a cross sectional view showing a device structure in one manufacturing step, particularly, a contact hole and a neighboring structure thereof by taking an EPROM as an example, for explaining a method for manufacturing another conventional semiconductor device including contact holes whose side wall is forwardly tapered.

### DETAILED DESCRIPTION OF THE INVENTION

There will now be described an embodiment of this invention with reference to the accompanying drawings.

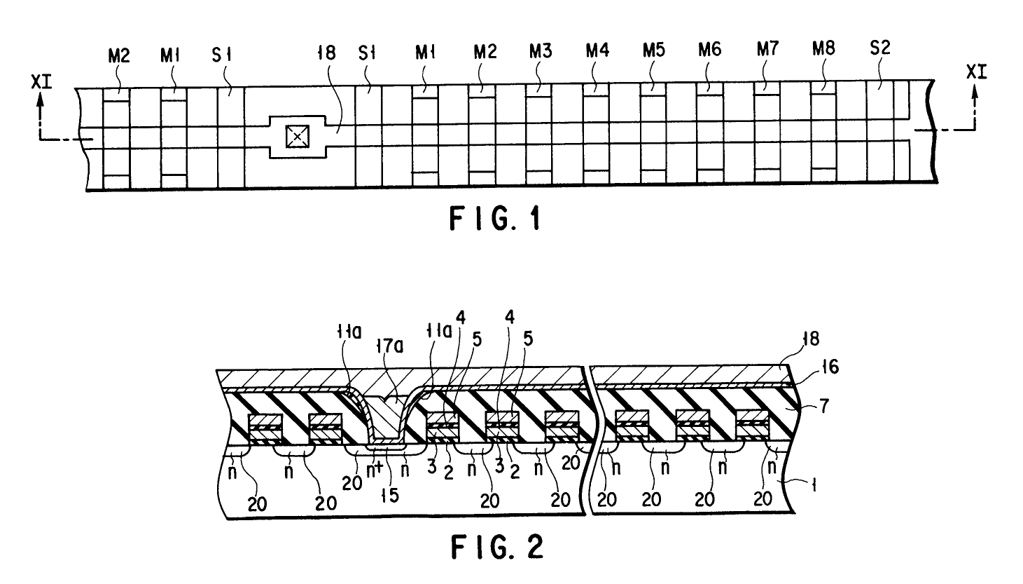

FIG. 1 is a plan pattern view showing a NAND type EEPROM according to an embodiment of the present invention, and FIG. 2 is a cross sectional view showing the NAND type EEPROM of the embodiment of the present invention, taken along the II-II line of FIG. 1.

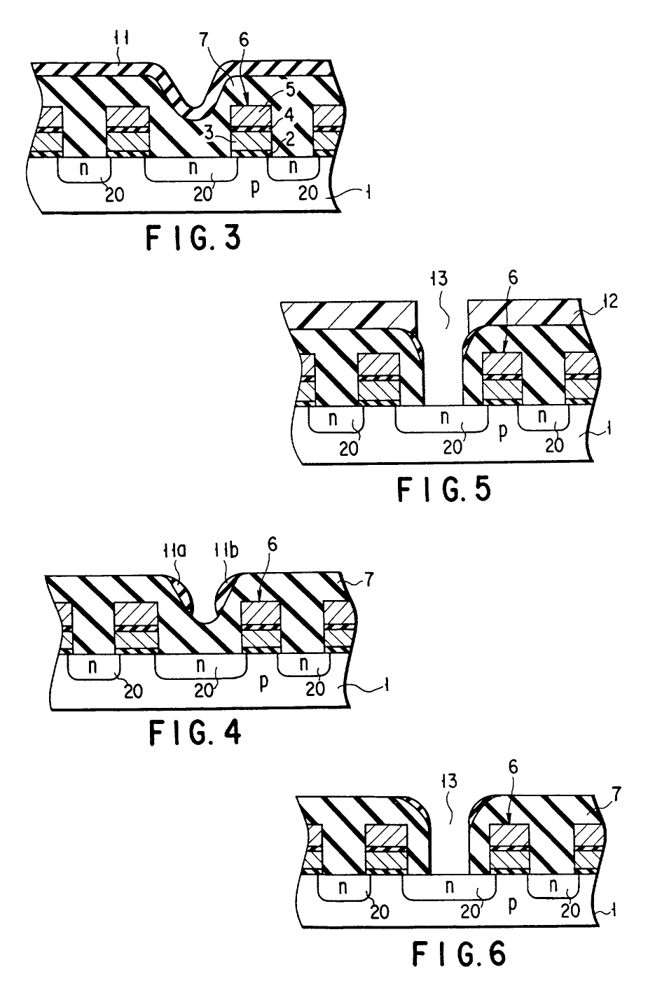

FIGS. 3 to 11 are cross sectional views each showing a device structure in one manufacturing step, particularly, a contact hole and a neighboring device structure thereof by taking the EEPROM of FIGS. 1 and 2 as an example, for explaining a semiconductor device and a method for manufacturing the same according to this invention.

As shown in FIGS. 1 and 2, one NAND cell is comprised of memory cells M1-M8 connected in series and a selecting gates S1 and S2. Selecting gate S1 is connected to the drain side terminal of the series connected memory cells M1-M8, and the selecting gate S2 is connected to the source side terminal of the series connected memory cells M1-M8. Memory cells M1-M8 and selecting gates S1 and S2 are connected in series and formed in, for example, a P type silicon substrate 1 surrounded by an element separating film (not shown). A contact between an N type diffusion layer 15 and a bit line 18 is taken at the drain side terminal of the NAND cell.

Referring to FIGS. 3 to 11, an explanation will be made with regard to a manufacturing process of a NAND type EEPROM, in particular, a contact portion thereof.

First, as shown in FIG. 3, material layers for first gate oxide films 2, floating gates 3, second gate oxide films 4 and control gates 5 are sequentially laminated on the surface of a P-type semiconductor substrate 1, for example, by the known manufacturing method and then the material layers are patterned to form laminated gate structures 6. After this, impurity is ion-implanted into the semiconductor substrate 1 with the laminated gate structures 6 used as a mask, and the implanted impurity ions are activated by the heat treatment to form source/drain regions 20 of a conductivity type opposite to that of the semiconductor substrate 1, thus forming memory cell transistors. The source/drain regions may be formed in the semiconductor substrate 1 before the laminated gate structures 6 are formed according to the shape of the pattern and the peripheral circuit. Then, an inter-level insulating film 7 is deposited to a thickness of approx. 0.3 μm to 0.5 μm on the entire surface of the semiconductor substrate by the atmospheric pressure CVD method so as to cover the laminated gate structures 6. The inter-level insulating film 7 is formed of SiO₂, for example. Alternatively, the inter-level insulating film 7 may be formed of SiO₂ containing impurity, for example, PSG or BPSG. Since a semiconductor integrated circuit is normally designed according to the minimum design rule, a space between the adjacent laminated gate structures 6 is small. Therefore, the space between the adjacent gate structures 6 is made substantially flat by the inter-level insulating film 7, but since a space in the contact hole forming portion is large, the inter-level insulating film 7 is not sufficiently deposited in the space and a concave portion is formed. As a result, a stepped portion is formed in the inter-level insulating film 7. Then, a CVD nitride film (CVD Si₃N₄ film) 11 is formed on the inter-level insulating film 7 by the low pressure CVD method which provides a preferable step coverage.

Next, as shown in FIG. 4, the CVD nitride film 11 is etched back by the RIE method to leave nitride films 11a, 11b on the side wall of the stepped portion (contact hole forming area).

Photoresist is coated on the inter-level insulating film 7 and the CVD nitride films 11a, 11b to form a photoresist film, the exposing and developing operations are effected for the photoresist film to form a photoresist pattern 12 used for forming contact holes as shown in FIG. 5, and then contact holes 13 which expose the semiconductor substrate 1 are formed by the RIE method in a condition of a high etching selective ratio with respect to the CVD nitride films 11a, 11b with the photoresist pattern 12 used as a mask. As shown in FIG. 5, the step of forming the contact hole 13 is effected by use of the SAC technique using the CVD nitride films 11a, 11b formed on the side wall of the stepped portion as etching stoppers.

Next, as shown in FIG. 6, the photoresist pattern 12 is removed.

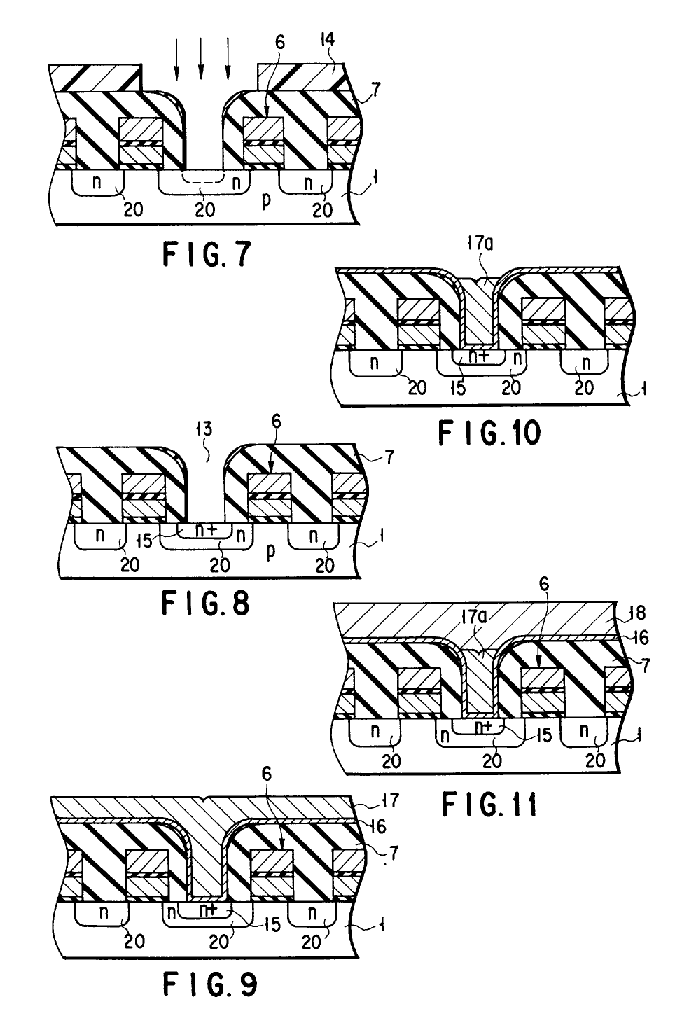

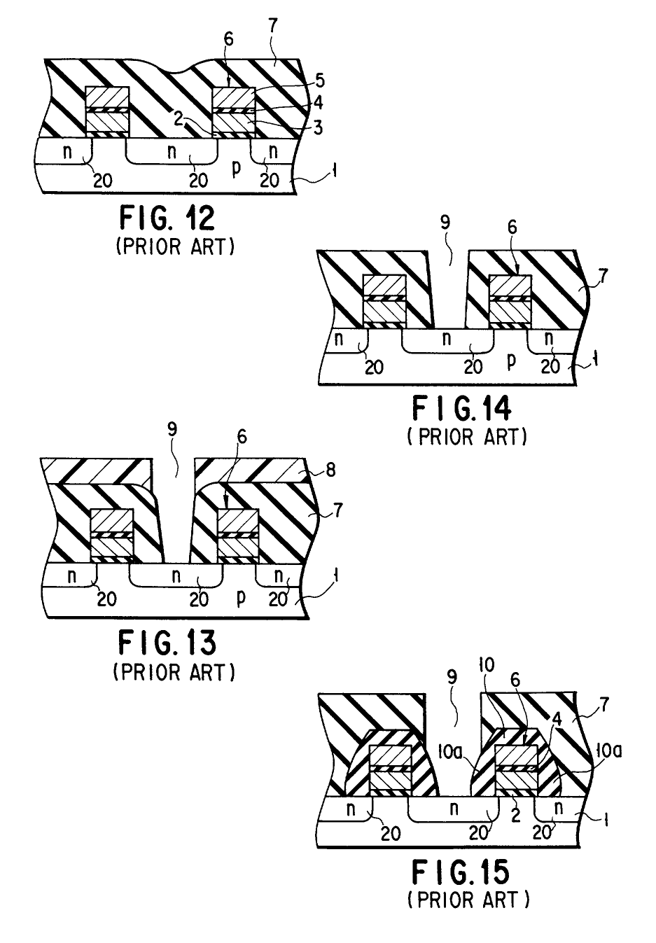

After this, as shown in FIG. 7, photoresist is coated on the inter-level insulating film 7 and the CVD nitride films 11a, 11b again to form a photoresist film and then the exposing and developing operations are effected for the photoresist film to form a resist mask 14. Impurity is ion-implanted into the exposed areas of the semiconductor substrate 1 in the bottom portions of the contact holes 13 via the contact holes 13 with the resist mask 14 used as a mask, and the ion-implanted impurity ions are subjected to the heat treatment and activated so as to form impurity diffusion layers 15 of high impurity concentration in the exposed areas as shown in FIG. 8. The impurity diffusion layer 15 is formed to reduce the contact resistance and prevent occurrence of the punch-through in the junction.

Next, as shown in FIG. 9, a barrier metal layer 16 is formed on the surface of the inter-level insulating film 7 and the exposed area (the area of the impurity diffusion layer 15) of the semiconductor substrate 1. Then, a filling material layer 17 is deposited on the barrier metal layer 16 to fill the contact hole 13 by the low pressure CVD method.

Next, the filling material layer 17 is etched back by the isotropic etching, for example, CDE (Chemical Dry Etching) and is left only in the contact hole 13 so as to form a plug 17a as shown in FIG. 10.

After this, as shown in FIG. 11, for example, aluminum is vapor-deposited on the barrier metal layer 16 and the filling material layer 17a to form an aluminum layer and the aluminum layer is patterned to form interconnection layers 18.

According to the structure and the manufacturing method described above, since the upper end portion of the contact hole 13 is formed in a forward tapered form, the margin for the short circuit between the side wall portion of the contact hole 13 and the laminated gate structure 6 can be made large while the area of the bottom portion of the contact hole 13 is kept sufficiently large and thus the reliability of the semiconductor device can be enhanced. Further, since the inter-level insulating film 7 is disposed between the laminated gate structure 6 and the CVD nitride films 11a, 11b which give large stress on the gate oxide films 2, 4, deterioration of the gate oxide films 2, 4 can be prevented and the hot carrier resistance will not be lowered. Further, since the CVD nitride films 11a, 11b which are difficult to pass ultraviolet rays therethrough are formed to cover only the upper end portion of the contact hole, time required for the erasing operation or initialization by application of ultraviolet rays can be reduced.

In the above embodiment, a case wherein the SiN film 11 acting as the stopper is formed without subjecting the inter-level insulating film 7 to the reflow process after deposition of the inter-level insulating layer 7 in the manufacturing step shown in FIG. 3 and then etched back by the etch-back method to leave the SiN films 11a, 11b on the side wall of the stepped portion is explained, but if the gist and effect of this invention are taken into consideration, it is clearly understood that the degree of flatness of the inter-level insulating film 7 is enhanced by reflow after the inter-level insulating film 7 is deposited, and then the SiN film 11 acting as the stopper is formed and etched back by the etch-back method to leave the SiN films 11a, 11b on the side wall of the stepped portion. Thus, the possibility of leaving the SiN film on unwanted portions can be suppressed by enhancing the degree of flatness of the inter-level insulating film 7 by reflow after deposition of the inter-level insulating film 7 and before deposition of the SiN film 11. Further, a case wherein the formation method of the SiN film acting as the etching stopper insulating film 11 (11a, 11b) is effected by the low pressure CVD method is explained, but the same effect can be attained even if another formation condition such as a atmospheric pressure CVD method is used instead of the low pressure CVD method. Further, the SiN film is used as the material of the etching stopper insulating film 11 (11a, 11b), but it is also possible to use another material instead of the SiN film if it has a sufficiently high etching selective ratio with respect to the inter-level insulating film 7. In addition, as shown in FIG. 15, it is possible to form etching stopper insulating films 10 to cover the upper surfaces of the laminated gate structures 6, and this invention can be variously modified without departing from the technical scope thereof.

As described above, according to this invention, a semiconductor device and a method for manufacturing the same in which the area of the bottom portion of the contact hole can be made large and the margin for the short circuit between the side wall of the contact hole and the semiconductor element can be made sufficiently large can be attained.

Further, a semiconductor device and a method for manufacturing the same in which a lowering in the hot carrier resistance due to deterioration of the gate oxide film can be suppressed can be attained.

Further, a semiconductor device and a method for manufacturing the same in which time required for the erasing operation or initialization by application of ultraviolet rays to the nonvolatile memory cell transistors can be reduced can be attained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a semiconductor element formed on a surface of said semiconductor substrate;
an inter-level insulating film formed above the surface of said semiconductor substrate to cover said semiconductor element;
a contact hole formed in said inter-level insulating film and having at least an upper end portion formed in a forward tapered form;
an insulating film formed on the upper end portion of said contact hole; and
a conductive filling material layer filled in said contact hole.

2. A semiconductor device according to claim 1, further comprising an impurity diffusion layer formed in a surface area of said semiconductor substrate in a bottom portion of said contact hole.

3. A semiconductor device according to claim 1, further comprising an interconnection layer formed on said inter-level insulating film and said filling material layer and electrically connected to said semiconductor element via said filling material layer.

4. A semiconductor device according to claim 1, further comprising a barrier metal layer formed between said filling material layer and a surface area of said semiconductor substrate in a bottom portion of said contact hole.

5. A semiconductor device according to claim 1, wherein said semiconductor element is a nonvolatile memory cell transistor.

6. A semiconductor device according to claim 1, wherein said insulating film formed on the upper end portion of the contact hole is formed of a material having a high etching selective ratio with respect to a material of said inter-level insulating film.

7. A semiconductor device according to claim 1, wherein said insulating film formed on the upper end portion of the contact hole is formed of an etching stopper material with regard to a material of said inter-level insulating film.

8. A semiconductor device according to claim 1, wherein said inter-level insulating film includes silicon oxide and said insulating film formed on the upper end portion of said contact hole is a silicon nitride film.

9. A method for manufacturing a semiconductor device comprising the steps of:
forming a semiconductor element on a surface of a semiconductor substrate;
forming an inter-level insulating film above the surface of the semiconductor substrate to cover the semiconductor element;
forming an insulating film having a high etching selective ratio with respect to the inter-level insulating film on the inter-level insulating film;
etching back the insulating film to leave a portion of the insulating film on a side wall of a stepped portion of a contact hole forming area on the inter-level insulating film; and
etching the inter-level insulating film by use of the insulating film left on the side wall of the stepped portion on the inter-level insulating film as an etching stopper to form contact hole having an upper end portion formed in a forward tapered form in the inter-level insulating film.

10. A method for manufacturing the semiconductor device according to claim 9, further comprising a step of ion-implanting impurity into a surface area of the semiconductor substrate in a bottom portion of the contact hole.

11. A method for manufacturing the semiconductor device according to claim 9, further comprising a step of forming a filling material layer by filling a conductive filling material into the contact hole.

12. A method for manufacturing the semiconductor device according to claim 11, further comprising a step of forming an interconnection layer on the inter-level insulating film and the filling material layer.

13. A method for manufacturing the semiconductor device according to claim 9, wherein said interconnection layer is formed by depositing a metal on the inter-level insulating film and the filling material layer.

14. A method for manufacturing the semiconductor device according to claim 9, further comprising a step of forming a barrier metal layer in the contact hole.

15. A method for manufacturing the semiconductor device according to claim 9, wherein said inter-level insulating film is formed by using atmospheric pressure CVD method.

16. A method for manufacturing the semiconductor device according to claim 9, wherein said insulating film having the high etching selective ratio is formed by using low pressure CVD method.

17. A method for manufacturing the semiconductor device according to claim 11, wherein said conductive filling material is formed by using low pressure CVD method and isotropic etching method.

18. A method for manufacturing the semiconductor device according to claim 9, wherein said step of forming the semiconductor element includes a step of forming a first gate insulating film on the semiconductor substrate, a step of forming a floating gate on the first gate insulating film, a step of forming a second gate insulating film on the floating gate, a step of forming a control gate on the second gate insulating film, and a step of forming source and drain regions in the semiconductor substrate.

19. A method for manufacturing the semiconductor device according to claim 9, wherein said inter-level insulating film includes a silicon oxide film formed by CVD method and said insulating film having the high etching selective ratio includes a silicon nitride film formed by CVD method.

20. A method for manufacturing the semiconductor device according to claim 9, further comprising a step of subjecting said inter-level insulating film to a reflow process before forming the insulating film having the high etching selective ratio.
